(19) United States
(12) Patent Application Publication
(10) Pub. No.: US 2026/0255951 A1
(43) Pub. Date: Aug. 27, 2026

(54) SEMICONDUCTOR DEVICE

(71) Applicant: Socionext Inc., Kanagawa (JP)

(72) Inventors: Hirotaka TAKENO, Yokohama (JP); Atsushi OKAMOTO, Yokohama (JP); Wenzhen WANG, Yokohama (JP)

(21) Appl. No.: 19/648,774

(22) Filed: Apr. 15, 2026

Related U.S. Application Data
(63) Continuation of application No. PCT/JP2023/037785, filed on Oct. 19, 2023.

(51) Int. Cl. H10W 20/41; H10W 20/20; H10W 20/43; H10D 30/00; H10D 30/43; H10D 62/10; H10D 84/85

(52) U.S. Cl. CPC H10W 20/427; H10W 20/2125; H10W 20/2134; H10W 20/43; H10W 20/435; H10D 30/43; H10D 30/502; H10D 62/121; H10D 84/851

(57) ABSTRACT

A semiconductor device includes a substrate, a first power supply line and a second power supply line, a conductive wall, a first semiconductor layer and a second semiconductor layer, a first through via, a second through via, a third semiconductor layer, a fourth semiconductor layer, a first gate, a first transistor, and a control circuit, wherein the control circuit includes a fifth semiconductor layer and a sixth semiconductor layer, a third through via, a seventh semiconductor layer, an eighth semiconductor layer, a second gate, a second transistor, and a third transistor, one of the seventh semiconductor layer or the eighth semiconductor layer is electrically connected to the conductive wall, and another one of the seventh semiconductor layer or the eighth semiconductor layer is electrically connected to the sixth semiconductor layer and the first gate of the first transistor.

### CROSS-REFERENCE TO RELATED APPLICATION

This application is a continuation application of International Application No. PCT/JP2023/037785, filed on October 19, 2023, and designated the U.S., the entire contents of which are incorporated herein by reference.

### BACKGROUND OF THE INVENTION

The disclosures herein relate to semiconductor devices.

There is a technology called CFET (Complementary Field Effect Transistor) which forms a CMOS (Complementary Metal-Oxide-Semiconductor) by arranging transistors in a direction perpendicular to a substrate. With the use of CFETs, a cell area of a CMOS basic cell is significantly reduced, and a semiconductor device is downsized. In a technology called BS-PDN (Backside Power Delivery Network) which supplies a power supply voltage to a circuit on a front surface of a semiconductor substrate from a back surface of the substrate, a configuration is used in which a Through Silicon Via (TSV) penetrating the substrate is directly connected to a source/drain of a transistor. There is a technology called a power wall in which a conductive wall is formed over the height of the upper and lower transistors of a CFET to supply power to each transistor. There is a technology in which a power switch circuit for controlling on and off of supply of a power supply voltage is provided in a circuit such as a standard cell.

In a circuit that supplies power to a CFET via a power wall, how to lay out a power switch circuit has not been studied in detail. The present disclosure aims to provide a semiconductor device having a configuration for supplying power via a power wall and having a power switch circuit effectively laid out.

### CITATION LIST

### PATENT LITERATURE

PTL 1 U.S. Patent Application Publication No. 2022/0068921

PTL 2 U.S. Patent Application Publication No. 2023/0178435

PTL 3 U.S. Patent Application Publication No. 2023/0067311

PTL 4 U.S. Patent Application Publication No. 2022/0123023

PTL 5 U.S. Patent Application Publication No. 2022/0181258

PTL 6 WO 2020/065916

PTL 7 WO 2020/066797

PTL 8 WO 2020/217396

PTL 9 WO 2020/217400

PTL 10 U.S. Patent Application Publication No. 2021/0366902

PTL 11 U.S. Patent Application Publication No. 2022/0102479

PTL 12 U.S. Patent Application Publication No. 2021/0210600

PTL 13 U.S. Patent No. 10950546

PTL 14 U.S. Patent No. 11004789

### SUMMARY OF THE INVENTION

A semiconductor device includes a substrate, a first power supply line and a second power supply line extending in a first direction in plan view on a first surface of the substrate, a conductive wall extending in the first direction and disposed offset from the first power supply line and the second power supply line in a second direction different from the first direction in plan view, a first semiconductor layer and a second semiconductor layer disposed on a second surface of the substrate opposite to the first surface, the first semiconductor layer being disposed at a position overlapping with the first power supply line in plan view, and the second semiconductor layer being disposed at a position overlapping with the second power supply line in plan view, a first through via formed in the substrate and connecting the first power supply line and the first semiconductor layer, a second through via formed in the substrate and connecting the second power supply line and the second semiconductor layer, a third semiconductor layer formed above the first semiconductor layer, a fourth semiconductor layer formed above the second semiconductor layer, a first gate disposed between the first semiconductor layer and the second semiconductor layer, and the third semiconductor layer and the fourth semiconductor layer, a first transistor including the first semiconductor layer, the second semiconductor layer, and the first gate, and a control circuit configured to control the first transistors, wherein the control circuit includes a fifth semiconductor layer and a sixth semiconductor layer, each formed on the second surface at a position overlapping with the first power supply line in plan view, a third through via each formed in the substrate and connecting the fifth semiconductor layer and the first power supply lines, a seventh semiconductor layer formed above the fifth semiconductor layer, an eighth semiconductor layer formed above the sixth semiconductor layer, a second gate disposed between the fifth semiconductor layer and the sixth semiconductor layer, and the seventh semiconductor layer and the eighth semiconductor layer, a second transistor including the fifth semiconductor layer, the sixth semiconductor layer, and the second gate, and a third transistor including the seventh semiconductor layer, the eighth semiconductor layer, and the second gate, and one of the seventh semiconductor layer or the eighth semiconductor layer is electrically connected to the conductive wall, and the other one of the seventh semiconductor layer or the eighth semiconductor layer is electrically connected to the sixth semiconductor layer and the first gate of the first transistor.

A semiconductor device having a configuration for supplying power via a power wall and having a power switch circuit effectively laid out is provided.

### BRIEF DESCRIPTION OF THE DRAWINGS

FIG. 1 is a schematic diagram illustrating an outline of a layout of a semiconductor device of an embodiment;

FIG. 2 is a schematic cross-sectional view illustrating an example of an interconnect structure of a circuit region of the semiconductor device;

FIG. 3 is a drawing illustrating an overview of the semiconductor device of the embodiment;

FIG. 4 is a plan view illustrating a backside metal (BSM) of the semiconductor device of the embodiment;

FIG. 5 is a plan view illustrating a bottom layer of the semiconductor device of the embodiment;

FIG. 6 is a plan view illustrating a top layer of the semiconductor device of the embodiment;

FIG. 7 is a cross-sectional view of FIGS. 4 to 6 taken along a line X1-X1′;

FIG. 8 is a cross-sectional view of FIGS. 4 to 6 taken along a line Y1-Y1′;

FIG. 9 is a plan view illustrating a bottom layer of a semiconductor device of a first modification example;

FIG. 10 is a plan view illustrating a top layer of the first modification example;

FIG. 11 is a plan view illustrating the BSM of a second modification example;

FIG. 12 is a plan view illustrating a bottom layer of the second modification example; and

FIG. 13 is a plan view illustrating a top layer of the second modification example.

### DESCRIPTION OF THE PREFERRED EMBODIMENTS

In an embodiment, in a semiconductor device in which a power wall is used for a part of power supply lines for supplying a power supply voltage to CFET, a power switch circuit is efficiently laid out. Particularly, an efficient arrangement relationship between a control circuit that controls switching of power supply to a standard cell and a power wall is achieved. In the following, a specific configuration of the semiconductor device of the present embodiment will be described with reference to the accompanying drawings. In addition, the embodiments described below are not intended to limit the invention but are examples, and all features and combinations thereof described in the embodiments are not necessarily essential to the invention. The sizes and positional relationships of the components shown in the drawings may be exaggerated to facilitate understanding of the invention. In the drawings, the same constituent elements are denoted with the same reference numerals, and redundant description thereabout may be omitted.

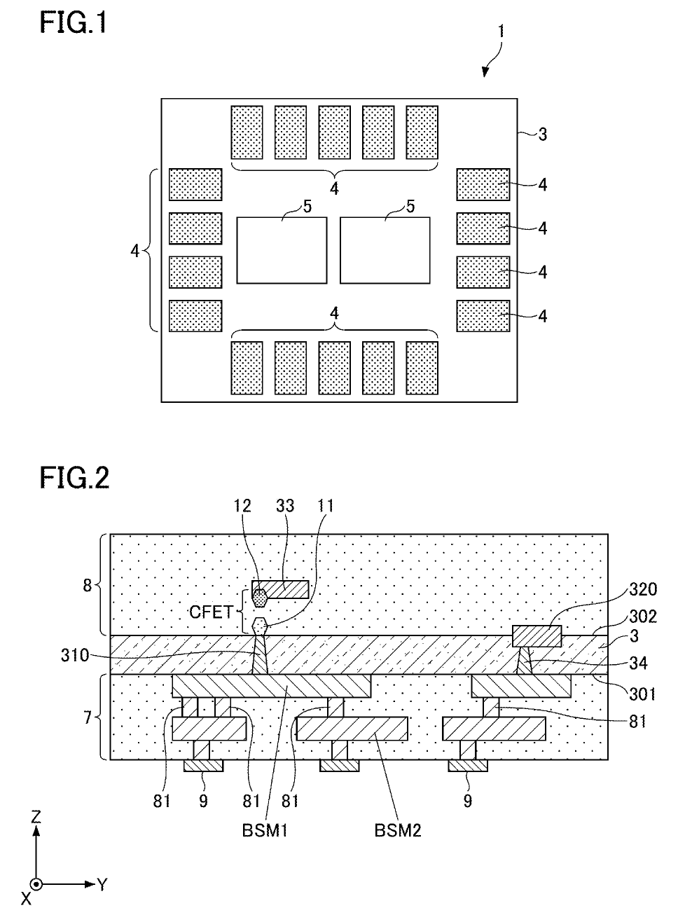

FIG. 1 is a schematic diagram illustrating an outline of a layout of a semiconductor device 1 according to the embodiment. The semiconductor device 1 has one or more circuit regions 5 disposed on a substrate 3 and a plurality of input and output (I/O) cell regions 4 disposed on the substrate 3. The circuit region 5 may have a standard cell including a plurality of logic circuits, or may have other circuits such as a gate array, SRAM (Static Random Access Memory), and analog circuits.

FIG. 2 is a schematic cross-sectional view illustrating an example of an interconnect structure of the circuit region 5 of the semiconductor device 1. In a coordinate system of FIG. 2, a plane parallel to the substrate 3 is referred to as an XY-plane, and a direction perpendicular to the substrate 3, that is, a stacking direction is referred to as a Z-direction. The semiconductor device 1 has a first interconnect layer 7 on a back surface 301 of the substrate 3 and a second interconnect layer 8 on a front surface 302 of the substrate. The semiconductor device 1 supplies a power supply voltage from the back surface 301 of the substrate 3 to a circuit on the front surface 302 of the substrate 3. Here, the back surface 301 of the substrate 3 is referred to as a “first surface” and the front surface 302 is referred to as a “second surface”. A CFET having a first transistor 11 and an upper transistor 12 in a direction perpendicular to the substrate 3 is disposed on the front surface 302 side of the substrate 3. The first transistor 11 may be referred to as a “bottom transistor” and the upper transistor may be referred to as a “top transistor”. In the present figure, sources and drains (hereinafter referred to as “source/drain”, as appropriate) of the first transistor 11 and a top transistor 12 are extended in an X-direction perpendicular to the drawing.

In the first interconnect layer 7, a power supply line for supplying an operating voltage of a circuit or a power supply interconnect for supplying a reference voltage lower than the operating voltage are formed. In the example shown in FIG. 2, a first layer interconnect (BSM1) on the back surface 301 of the substrate 3 and a second layer interconnect (BSM2) on the back surface 301 are provided. An interconnect BSM1 of the first layer and an interconnect BSM2 of the second layer are connected via a via plug 81. A pad 9 serving as an external connection terminal is formed on the lowermost surface of the first interconnect layer 7. The first interconnect layer 7 may be an interconnect layer formed directly on the back surface 301 of the substrate 3 or an interconnect layer formed on another chip (i.e., a substrate) bonded to the back surface 301 of the substrate 3.

The interconnects BSM1 and BSM2 of the first interconnect layer 7 are connected to the semiconductor layer of the first transistor 11 of CFET via a through via 310 penetrating the substrate 3. The interconnects BSM1 and BSM2 of the first interconnect layer 7 are connected to a source of the top transistor 12 of CFET via a through via (not shown) provided in the substrate 3 and an interconnect 33 formed in the second interconnect layer 8. An embedded interconnect 320 connected to a through via 34 may be provided on the front surface 302 side of the substrate 3. The connection between the interconnect on the back surface 301 of the substrate 3 and the top transistor 12 on the upper side of CFET may be achieved, as will be described later, by a conductive wall (also referred to as a “power wall”) extending vertically from the back surface 301 toward the front surface 302 side of the substrate 3 and the interconnect 33 connected to the conductive wall.

### OUTLINE OF SEMICONDUCTOR DEVICE OF EMBODIMENT

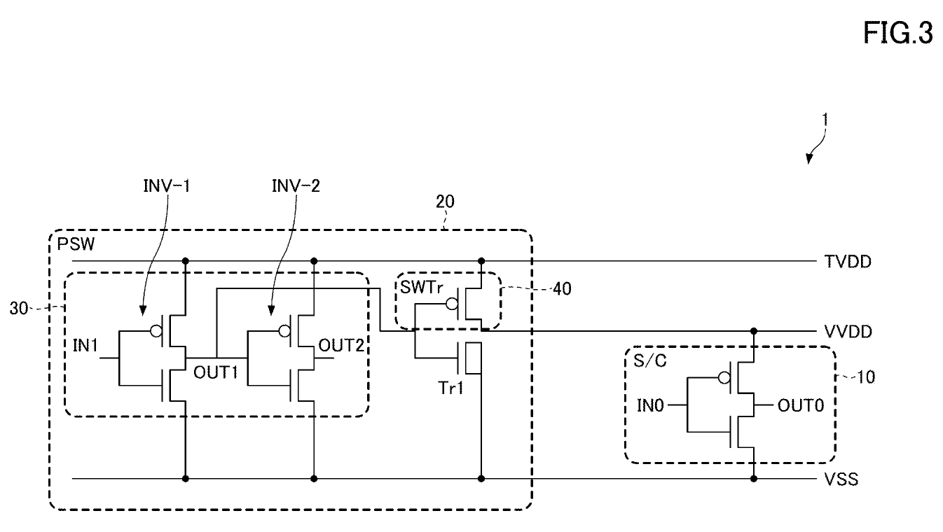

FIG. 3 is a drawing illustrating an overview of the semiconductor device 1. The semiconductor device 1 includes a standard cell 10 and a power switch circuit (referred to as “PSW” in the figure) 20 for switching on and off the supply of power to the standard cell 10. The standard cell 10 has a circuit of the smallest unit for performing a basic operation by various logic circuits such as NAND, NOR, AOI (AND-OR INV), and flip-flop. In the example of FIG. 3, the standard cell 10 is an inverter, but it is not limited to this example, and other logic circuits may be used.

A power switch circuit 20 includes a switch transistor 40 for switching on and off the supply of power to the standard cell 10 and a control circuit 30 for controlling the switch transistor (referred to as “SWTr” in the figure) 40. In a configuration in which the power switch circuit 20 switches on and off the supply of power to circuits such as the standard cell 10, three types of power supply lines are used: a true VDD (TVDD), a virtual VDD (VVDD), and VSS. TVDD and VVDD supply an operating voltage of the circuit. VSS supplies a reference voltage, which is lower than VDD. As will be described later, the power supply line VSS has a conductive wall (or power wall) perpendicular to the substrate.

The standard cell 10 is electrically connected between VSS and VVDD. The power switch circuit 20 is electrically connected between VSS and TVDD. If the power supply voltage is always supplied to the standard cell 10 even when the standard cell 10 is not in use, leakage may occur and power consumption may increase. In order to prevent this, the standard cell 10 is connected to VVDD, which is a virtual power supply line, and the power supply voltage is supplied from TVDD to VVDD when necessary. The power supply from TVDD to VVDD to which the standard cell is connected is executed by the switch transistor 40 based on a command from the control circuit 30. The switch transistor 40 is composed of a PMOS transistor in this example, and its source is connected to TVDD, and its drain is connected to VVDD. When a signal IN0 is input to a gate of the standard cell 10 with the power supply voltage being supplied to VVDD, a signal OUT0 is output from drains of PMOS and NMOS.

The control circuit 30 has, for example, inverters INV-1 and INV-2. Each of the inverters INV-1 and INV-2 may have a CFET structure. When a signal “IN1” is input to the gate of the first-stage inverter INV-1, a signal “OUT1” is output from the inverter INV-1. The signal “OUT1” is input to the gate of the second-stage inverter INV-2 and, as an output of the control circuit 30, to the gate of the switch transistor 40. The second-stage inverter INV-2 outputs a signal “OUT2” to the outside. The switch transistor 40 switches on and off the supply of the power supply voltage from TVDD to VVDD based on the signal “OUT1” from the control circuit 30. In the configuration example of FIG. 3, the switch transistor 40 is controlled by the signal “OUT1” from the node between the inverters INV-1 and INV-2, but this example is not limited. Any configuration for controlling on and off the supply of the power supply voltage to the switch transistor 40, such as using a single inverter, can be adopted.

A transistor Tr1 similar to NMOS is connected to the gate of the switch transistor 40 formed of PMOS. The switch transistor 40 and the transistor Tr1 may form a CFET arranged in a direction perpendicular to the substrate and connected to a common gate. In FIG. 3, portions corresponding to the source and drain of the transistor Tr1 are connected to VSS but may be floating. The transistor Tr1 may be a dummy top transistor formed by a process common to the standard cell 10 and CFET of the control circuit 30. Further, instead of forming a dummy top transistor, formation of some top transistors may be omitted.

When switching on and off the power supply to the standard cell 10 in a circuit using three types of power supply lines, that is, TVDD, VVDD, and VSS, it is important to determine how to design a specific interconnect of the power switch circuit 20. Since a VSS interconnect is formed as a conductive wall (power wall) extending in a perpendicular direction from the front surface 302 of the substrate 3 and connected to both the power switch circuit 20 and the standard cell 10, an efficient connection structure is required. In particular, an efficient layout is required when the power switch circuit 20 is connected between TVDD and VSS, and the standard cell 10 is connected between VVDD and VSS.

### SPECIFIC CONFIGURATION OF SEMICONDUCTOR DEVICE

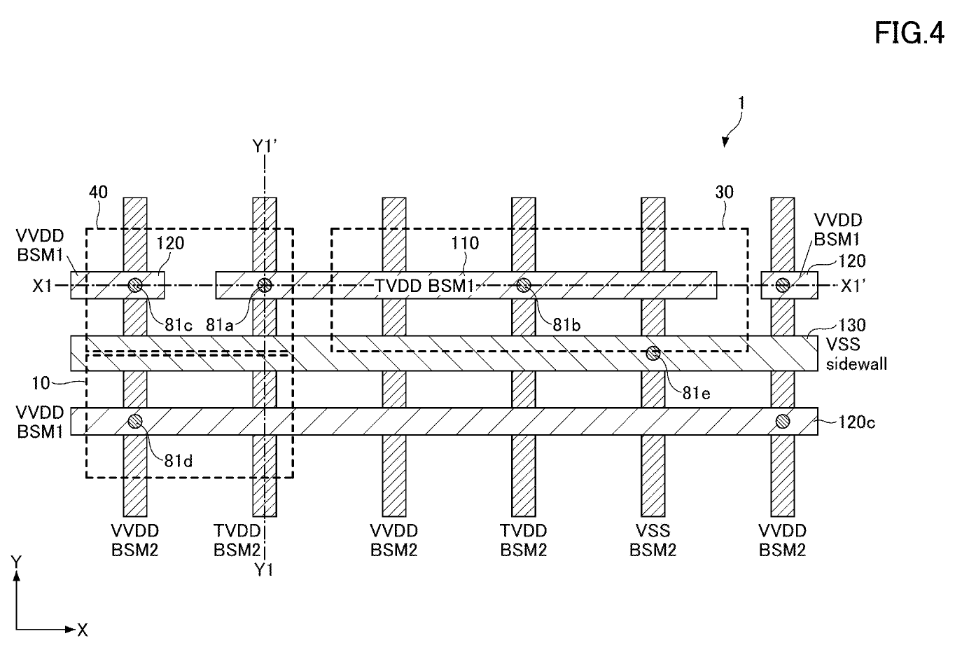

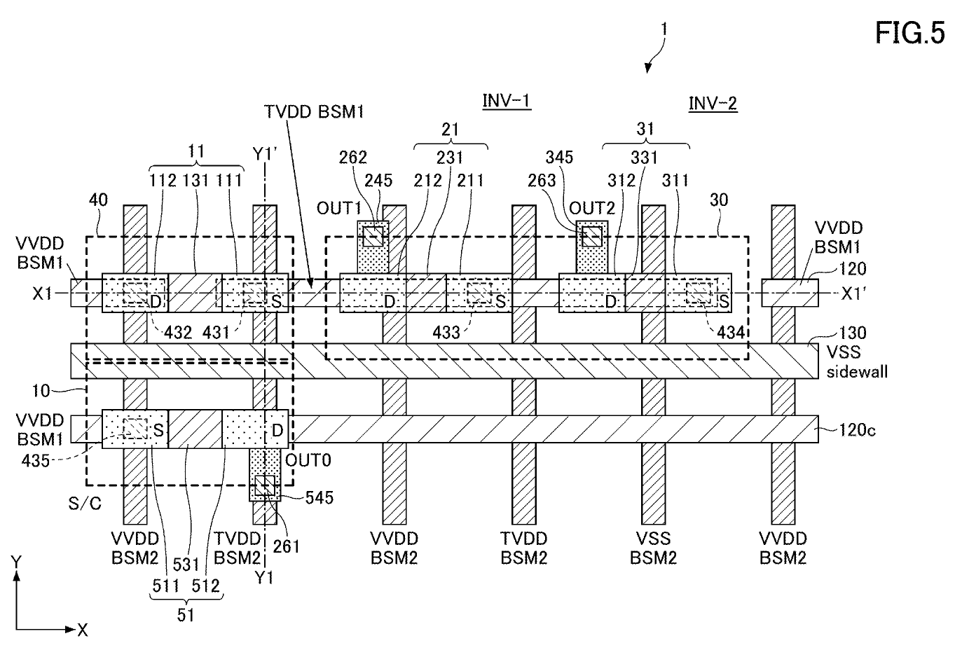

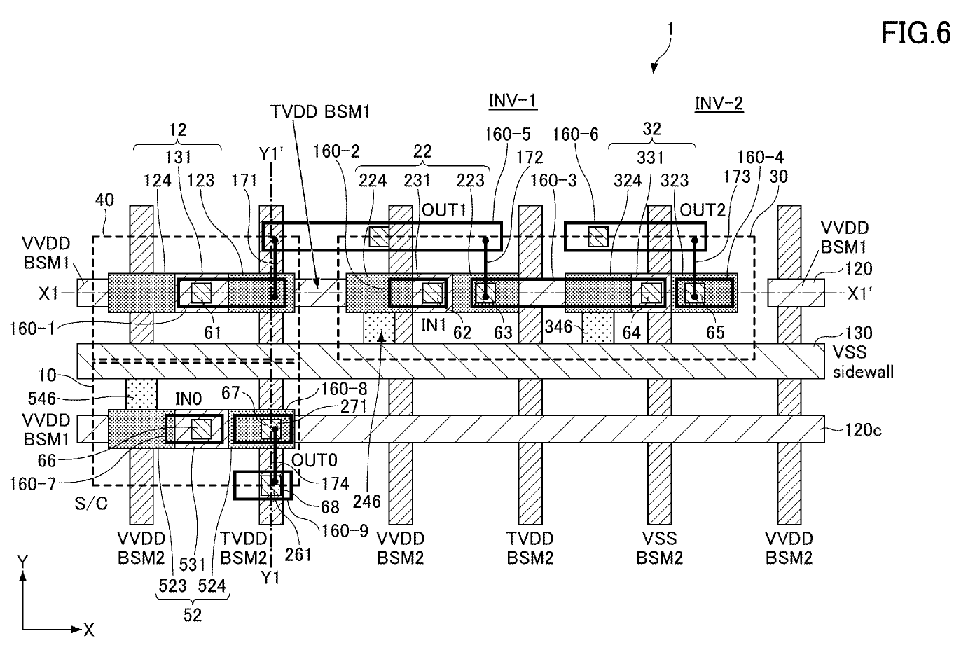

FIG. 4 is a plan view illustrating a BSM of the semiconductor device 1 of the embodiment, FIG. 5 is a plan view illustrating a bottom layer, and FIG. 6 is a plan view illustrating a top layer. The BSM is an interconnect layer included in the first interconnect layer 7 on the back surface 301 side of the substrate 3 (see FIG. 2), the bottom layer is a layer including the first transistor 11 of CFET provided on the front surface 302 side of the substrate 3, and the top layer is a layer including the top transistor 12 of the CFET. In the coordinate axes of FIGS. 4 to 6, a direction indicated by an arrow indicating an X-direction or a Y-direction in the drawing is referred to as a plus (+) direction, and a direction opposite to the plus direction is referred to as a minus (−) direction.

### EXAMPLE OF PLANAR ARRANGEMENT OF BSM

In FIG. 4, TVDD 110, which is a first power supply line, is extended in a first direction (e.g., X-direction) in a region corresponding to the control circuit 30 in the back surface first layer (BSM1). Alongside TVDD 110 extending in the X-direction, VVDD 120, which is a second power supply line, is extended in the first direction. The switch transistor 40 is arranged in a region including an end of TVDD 110 on the -X side and VVDD 120.

A VSS sidewall 130, which is a power supply line for supplying a reference voltage, extends in the X-direction from TVDD 110 and VVDD 120 while being disposed offset in a second direction different from the first direction. In the example shown in FIG. 4, the VSS sidewall 130 is arranged offset from TVDD 110 and VVDD 120 in a -Y-direction. The VSS sidewall is a conductive wall extending from the back surface 301 of the substrate 3 through the substrate 3 to a height greater than or equal to the height of CFET on the front surface 302 side. The VSS sidewall 130 may be a conductive wall extending from the front surface of the substrate 3 to a height of the CFET top transistor. In this case, a through via formed in the substrate 3 may be connected to the VSS sidewall 130, and a reference voltage may be supplied to the VSS sidewall 130 through the through via. The VSS sidewall 130 may also be a conductive wall extending to a position higher than the top transistor of the CFET. Alternatively, a sidewall to which an operating voltage is supplied may be disposed in place of the VSS sidewall 130, and a power supply line to which a reference voltage is supplied may be disposed on the back surface of the substrate 3.

VVDD 120c (third power supply line) extending continuously in the X-direction is provided on the opposite side of TVDD 110 and VVDD 120 across the VSS sidewall 130. A region in which CFET of the standard cell 10 is provided is defined by using a part of VVDD 120c. When a power supply voltage is supplied from TVDD 110 to VVDD 120 by the switch transistor 40 in accordance with a control signal from the control circuit 30, the standard cell 10 receives the power supply and operates.

On a back surface second layer (BSM2) of the substrate 3, TVDD, VVDD, and VSS interconnects extending in the Y-direction are formed. TVDD 110 of the first layer (BSM1) is connected to the corresponding TVDD of the second layer (BSM2) via via plugs 81a and 81b. In a region where the switch transistor 40 is provided, VVDD 120 of the first layer (BSM1) is connected to the corresponding VVDD of the second layer (BSM2) via a via plug 81c. In a region where the standard cell 10 is provided, VVDD 120c of the first layer (BSM1) is connected to the corresponding VVDD of the second layer (BSM2) via a via plug 81d. The VSS sidewall 130 of the first layer (BSM1) is connected to the VSS interconnect (denoted as “VSS BSM2” in the figure) of the second layer (BSM2) via a via plug 81e.

### PLANAR ARRANGEMENT EXAMPLE OF BOTTOM LAYER

FIG. 5 is a plan view illustrating the bottom layer of the front surface 302 of the substrate 3. The VSS sidewall 130 extending in the X-direction penetrates the substrate 3 and has a height equal to or greater than the height of the CFET on the front surface 302 side. In the region of the switch transistor 40, a first semiconductor layer 111 overlapping TVDD 110 on the back surface in plan view and a second semiconductor layer 112 overlapping VVDD 120 on the back surface in plan view are provided. The first semiconductor layer 111 is connected to TVDD 110 on the back surface 301 of the substrate 3 via a first through via 431 penetrating the substrate 3. The second semiconductor layer 112 is connected to VVDD 120 on the back surface 301 of the substrate 3 via a second through via 432 penetrating the substrate 3.

A gate 131 is provided between the first semiconductor layer 111 and the second semiconductor layer 112 to form the first transistor 11. The first transistor 11 corresponds to a switch transistor SWTr (see FIG. 3). The gate 131 extends in a direction perpendicular to the XY-plane and is used in common with the first transistor 11 and the upper transistor Tr1 (see FIG. 3). A first conductivity type (e.g., p-type) impurity is added to the first semiconductor layer 111 and the second semiconductor layer 112. As will be described later with reference to FIG. 6, a third semiconductor layer and a fourth semiconductor layer are provided above the first semiconductor layer 111 and the second semiconductor layer 112, respectively, and a top transistor is formed of the third semiconductor layer, the fourth semiconductor layer, and the gate 131.

In the region of the control circuit 30, a fifth semiconductor layer 211 and a sixth semiconductor layer 212 are provided, which overlap TVDD 110 on the back surface in plan view. The first conductivity type impurity is added to the fifth semiconductor layer 211 and the sixth semiconductor layer 212. A gate 231 is provided between the fifth semiconductor layer 211 and the sixth semiconductor layer 212, and a bottom transistor 21 (second transistor) of the inverter INV-1 in the preceding stage is formed. Which of the semiconductor layers of the bottom transistor 21 is used as a source or a drain depends on the design of the interconnect. The fifth semiconductor layer 211 of the bottom transistor 21 is connected to TVDD 110 on the back surface of the substrate 3 via a third through via 433 penetrating the substrate 3. The sixth semiconductor layer 212 is connected to an interconnect 245 extending in the Y-direction. A signal “OUT1” of the bottom transistor 21 is routed to an interconnect on a higher layer via a via plug 262 connected to the interconnect 245.

A bottom transistor 31 of the inverter INV-2 is formed adjacent to the bottom transistor 21 of the inverter INV-1 in the X-direction. The bottom transistor 31 has a source 311 and a drain 312 which are semiconductor layers overlapping TVDD 110 on the back surface in plan view. A gate 331 is provided between the source 311 and the drain 312. Which of the semiconductor layers of the bottom transistor 31 is used as the source or the drain depends on the interconnect design. Here, for convenience, one semiconductor layer of the bottom transistor 31 is referred to as the “source 311” and the other semiconductor layer is referred to as the “drain 312”. Impurities of the first conductivity type are added to the source 311 and the drain 312. The source 311 is connected to TVDD 110 on the back surface 301 via a through via 434 penetrating the substrate 3. The drain 312 is connected to an interconnect 345 extending in the Y-direction, and a signal “OUT2” of the bottom transistor 31 is routed to an interconnect on a higher layer via a via plug 263 connected to the interconnect 345.

In the region of the standard cell 10, in plan view, one semiconductor layer of a bottom transistor 51 is provided at a position coinciding with an intersection of VVDD 120c extending in the X-direction and the second layer VVDD extending in the Y-direction, and the other semiconductor layer of the bottom transistor 51 is provided at a position overlapping the intersection of VVDD 120c and the second layer TVDD extending in the Y-direction. Which of the semiconductor layers of the bottom transistor 51 is used as the source or the drain depends on the design of the interconnect. Here, for convenience, one semiconductor layer of the bottom transistor 51 is referred to as “a source 511”, and the other semiconductor layer is referred to as “a drain 512”. Impurities of the first conductivity type are added to the source 511 and the drain 512. A gate 531 is provided between the source 511 and the drain 512 to form the bottom transistor 51 of the standard cell 10. The source 511 is connected to VVDD 120c of the back surface 301 via a through via 435 penetrating the substrate 3. The drain 512 is connected to an interconnect 545 extending in the -Y-direction, and a signal “OUT0” of the bottom transistor 51 is routed to an interconnect on a higher layer via a via plug 261 connected to the interconnect 545.

In accordance with a signal “OUT1” output from the inverter INV-1 and input to the gate of the first transistor 11, on and off of supply of a power supply voltage from TVDD 110 to VVDD 120 is controlled. When the first transistor 11 is turned on, a power supply voltage is supplied from VVDD 120 to the standard cell 10 via the second layer VVDD (denoted as “VVDD BSM2” in the figure), VVDD 120c, and the through via 435.

### TOP LAYER PLAN CONFIGURATION EXAMPLE

FIG. 6 is a plan view illustrating a top layer of the front surface 302 of the substrate 3. In the region of the switch transistor 40, a third semiconductor layer 123 is provided above the first semiconductor layer 111, and a fourth semiconductor layer 124 is provided above the second semiconductor layer 112. The gate 131 used in common with the first transistor 11 is provided between the third semiconductor layer 123 and the fourth semiconductor layer 124 to form the top transistor 12. The top transistor 12 corresponds to the transistor Tr1 in FIG. 3. For example, the VSS sidewall 130 extending in the X-direction has a height equal to or greater than the height of the top transistor 12.

A second conductivity type (e.g., n-type) impurity different from the first conductivity type is added to the third semiconductor layer 123 and the fourth semiconductor layer 124 of the top transistor 12. The third semiconductor layer 123 and the fourth semiconductor layer 124 may be connected to the VSS sidewall 130, but in this example, they are floating. In the present disclosure, a portion that does not operate as a transistor, such as the top transistor 12, is also referred to as a transistor. The gate 131 of the top transistor 12 is connected to an upper interconnect 160-1 via a via plug 61, and receives a signal “OUT1” output from the inverter INV-1.

In the region of the control circuit 30, a seventh semiconductor layer 223 and an eighth semiconductor layer 224 are provided above the fifth semiconductor layer 211 and the sixth semiconductor layer 212 of the bottom transistor 21, respectively. The gate 231 used in common with the bottom transistor 21 is disposed between the seventh semiconductor layer 223 and the eighth semiconductor layer 224. The top transistor 22 (third transistor) of the inverter INV-1 is formed of the seventh semiconductor layer 223, the eighth semiconductor layer 224, and the gate 231. In the example of FIG. 6, the eighth semiconductor layer 224 is connected to the VSS sidewall 130 via an interconnect 246 extending in the -Y-direction, and the seventh semiconductor layer 223 is electrically connected to the sixth semiconductor layer 212 of the bottom transistor 21 and the gate 131 of the first transistor 11 which is a switch transistor. The seventh semiconductor layer 223 and the sixth semiconductor layer 212 output a signal “OUT1” output from the inverter INV-1. In this example, the eighth semiconductor layer 224 serves as a source and is connected to the VSS sidewall 130 via the interconnect 246, but the source and drain may be reversed depending on the interconnect structure. The gate 231 of the inverter INV-1 is electrically connected to an upper interconnect 160-2 via a via plug 62. The seventh semiconductor layer 223 is electrically connected to an upper interconnect 160-3 via a via plug 63. The upper interconnects 160-1 and 160-3 are further connected to the interconnect 160-5 formed on the same layer as the interconnect 160-1 and 160-3 via upper interconnects 171 and 172.

The signal “OUT1” output from the seventh semiconductor layer 223 of the top transistor 22 is led to upper interconnects 172 and 160-5 and becomes the output signal of the inverter INV-1 together with the “OUT1” output from the sixth semiconductor layer 212 of the bottom transistor 21. The signal “OUT1” as the output of the inverter INV-1 is applied to the gate 131 of the switch transistor 40 through the upper interconnects 171 and 160-1, and to the gate 331 of the inverter INV-2 through the upper interconnect 160-3. That is, the source of the top transistor 22 is connected to the VSS sidewall 130 through the interconnect 246, and the drain of the top transistor 22 is electrically connected to the sixth semiconductor layer 212 as the drain of the bottom transistor 21, the gate 131 of the switch transistor 40, and the gate 331 of the inverter INV-2.

The top transistor 32 of the inverter INV-2 is formed adjacent to the top transistor 22 of the inverter INV-1 in the X-direction. The top transistor 32 has a drain 323 provided above the source 311 of the bottom transistor 31, and a source 324 provided above the drain 312 of the bottom transistor 31. The gate 331 used in common with the bottom transistor 31 is arranged between the source 324 and the drain 323, and the top transistor 32 of the inverter INV-2 is formed. The source 324 of the inverter INV-2 is connected to the VSS sidewall 130 via an interconnect 346 extending in the -Y-direction. The gate 331 is connected to an interconnect 160-3 on an upper layer via a via plug 64. The drain 323 is connected to an interconnect 160-4 on an upper layer via a via plug 65. The interconnect 160-4 on an upper layer is connected to an interconnect 160-6 provided on the same layer as the interconnect 160-4 via an interconnect 173 on an upper layer.

In the region of the standard cell 10, a source 523 and a drain 524 are provided above the source 511 and the drain 512 of the bottom transistor 51, respectively. Impurities of the second conductivity type are added to the source 523 and the drain 524. The gate 531 common to the bottom transistor 51 is provided between the source 523 and the drain 524, and a top transistor 52 of the standard cell 10 is formed. The CFET of the standard cell 10 is formed of the bottom transistor 51 and the top transistor 52. The source 523 of the top transistor 52 is connected to the VSS sidewall 130 via an interconnect 546 extending in the Y-direction. The gate 531 is connected to an interconnect 160-7 on a higher layer via a via plug 66. The drain 524 is connected to an interconnect 160-8 on a higher layer via a via plug 67. The interconnect 160-8 on a higher layer is connected to an interconnect 160-9 provided on the same layer as the interconnect 160-8 via an interconnect 174 on a higher layer, and a signal “OUT0” output from the standard cell 10 is routed to the outside.

With the configuration shown in FIGS. 4, 5, and 6, the switch transistor 40 and the control circuit 30 for controlling the switch transistor 40 can be arranged in the vicinity of the standard cell 10 connected to the VSS sidewall 130.

### CROSS-SECTIONAL STRUCTURE

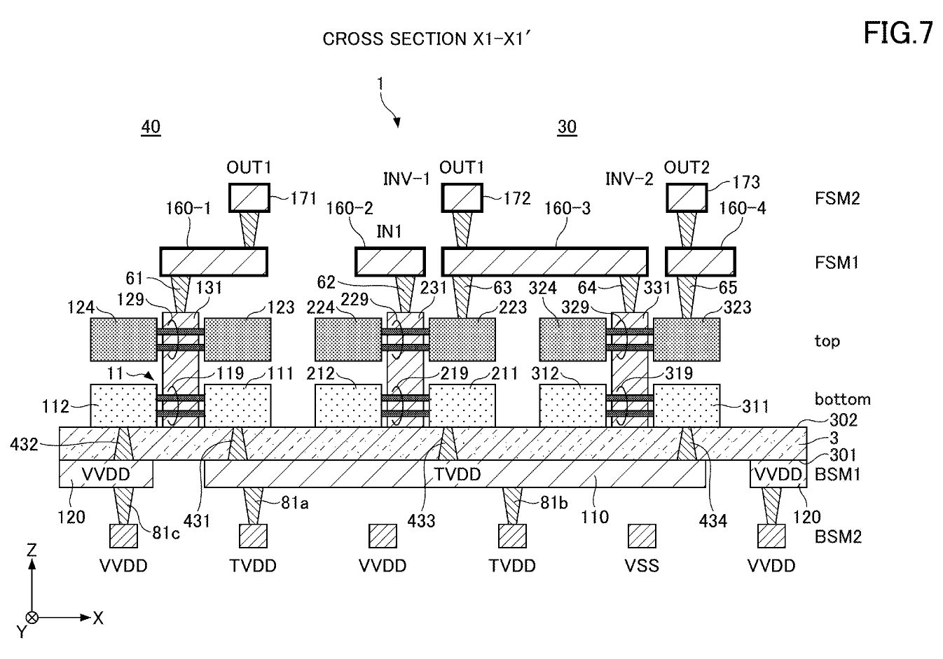

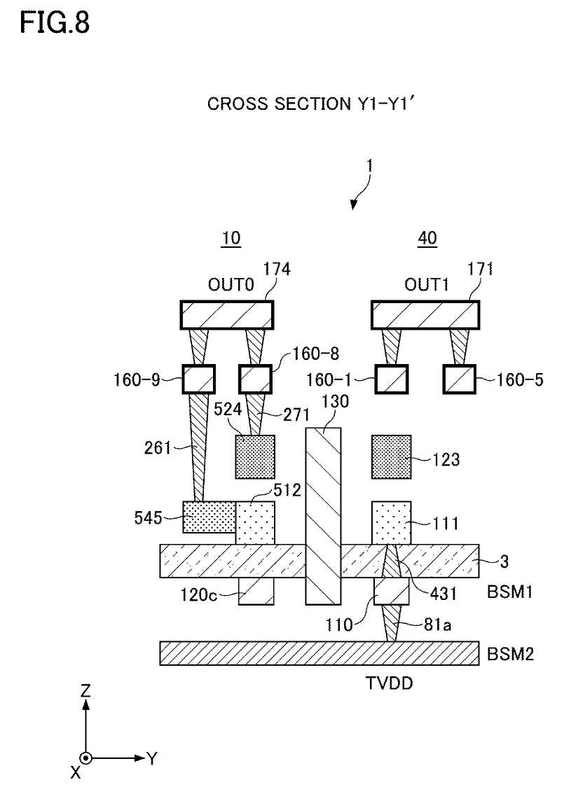

FIG. 7 is a cross-sectional view of FIGS. 4 to 6 taken along a line X1-X1′, and FIG. 8 is a cross-sectional view of FIGS. 4 to 6 taken along a line Y1-Y1′. A cross section X1-X1′ is a vertical cross section of the switch transistor 40 and the control circuit 30 along TVDD 110 and VVDD 120. A cross section Y1-Y1′ is a vertical cross section of a line perpendicular to the line X1-X1′ and passing through the switch transistor 40 and the standard cell 10.

In the cross section X1-X1′ of FIG. 7, TVDD 110 and VVDD 120 are arranged in the X-direction in the first layer (BSM1) of the back surface 301 of the substrate 3. TVDD 110 is connected to a TVDD line extending in the Y-direction in the back surface second layer (BSM2) via via plugs 81a and 81b. In the region of the switch transistor 40, VVDD 120 is connected to a VVDD line extending in the Y-direction in the back surface second layer (BSM2) via the via plug 81c.

In the region of the switch transistor 40 in the bottom layer on the front surface 302 side of the substrate 3, the first semiconductor layer 111 overlapping the end of TVDD 110 in plan view and the second semiconductor layer 112 overlapping VVDD 120 in plan view are provided. The first semiconductor layer 111 is connected to TVDD 110 via the first through via 431, and the second semiconductor layer 112 is connected to VVDD 120 via a second through via 432. The first semiconductor layer 111 and the second semiconductor layer 112 are connected via a channel 119 formed of a nanosheet. The fifth semiconductor layer 211 and the sixth semiconductor layer 212 in the bottom layer of the inverter INV-1 included in the control circuit 30 are connected via a channel 219 formed of a nanosheet. The source 311 and the drain 312 in the bottom layer of the inverter INV-2 are connected via a channel 319 formed of a nanosheet.

In the top layer, a third semiconductor layer 123 is provided above the first semiconductor layer 111 and a fourth semiconductor layer 124 is provided above the second semiconductor layer 112 in the region of the switch transistor 40. The third semiconductor layer 123 and the fourth semiconductor layer 124 are connected via a channel 129 formed of a nanosheet. Between the first semiconductor layer 111 and the second semiconductor layer 112 and between the third semiconductor layer 123 and the fourth semiconductor layer 124, the gate 131 reaching a height from the front surface 302 of the substrate 3 equal to or greater than the heights of the third semiconductor layer 123 and the fourth semiconductor layer 124 is provided. The gate 131 is electrically connected to the upper interconnect 160-1 via the via plug 61. The first transistor 11 is formed of the first semiconductor layer 111, the second semiconductor layer 112, and the gate 131 provided between the first semiconductor layer 111 and the second semiconductor layer 112. The first transistor 11 is the switch transistor 40 for turning on and off the supply of a power supply voltage to the standard cell 10.

In the top layer of the inverter INV-1, the seventh semiconductor layer 223 and the eighth semiconductor layer 224 are connected via a channel 229 formed of a nanosheet. In the top layer of the inverter INV-2, the seventh semiconductor layer and the eighth semiconductor layer are connected via a channel 329 formed of a nanosheet. The signal “OUT1” output from the inverter INV-1 is applied to the gate 131 of the switch transistor 40 through the upper interconnects 172, 171, and 160-1 and the via plug 61. The switch transistor 40 is controlled to be on or off according to the signal “OUT1” applied to the gate 131. When the first transistor 11 is on, the supply of the power supply voltage from TVDD 110 to VVDD 120 is turned on, and the CFET of the standard cell 10 operates.

In a cross section Y1-Y1′ of FIG. 8, the switch transistor 40 and the standard cell 10 are arranged across the VSS sidewall 130. The first semiconductor layer 111 of the switch transistor 40 is connected to TVDD 110 via the first through via 431 penetrating the substrate 3. A third semiconductor layer 123 is provided above the first semiconductor layer 111. A signal “OUT1” is input from the control circuit 30 to the gate 131 (see FIG. 7) of the switch transistor 40 via upper layer interconnects 160-5, 171, and 160-1.

In the standard cell 10, the drain 512 of the bottom transistor is provided at a position overlapping VVDD 120c in plan view, and the drain 524 of the top transistor is formed above the drain 512. A signal of the bottom transistor is led out to an upper layer interconnect 160-9 via the interconnect 545 extending from the drain 512 of the bottom transistor in the -Y-direction and the via plug 261. The drain 524 of the top transistor is connected to an upper layer interconnect 160-8 via a via plug 271. The upper layer interconnect 160-8 and 160-9 are connected to an upper layer interconnect 174, and a signal “OUT0” of the standard cell 10 is output to the outside.

By supplying the power supply voltage from TVDD 110 to VVDD 120 by the switch transistor 40 on the basis of the signal “OUT1” from the control circuit 30, the power supply voltage is supplied to the standard cell 10 when necessary, thereby reducing power consumption.

### First Modification

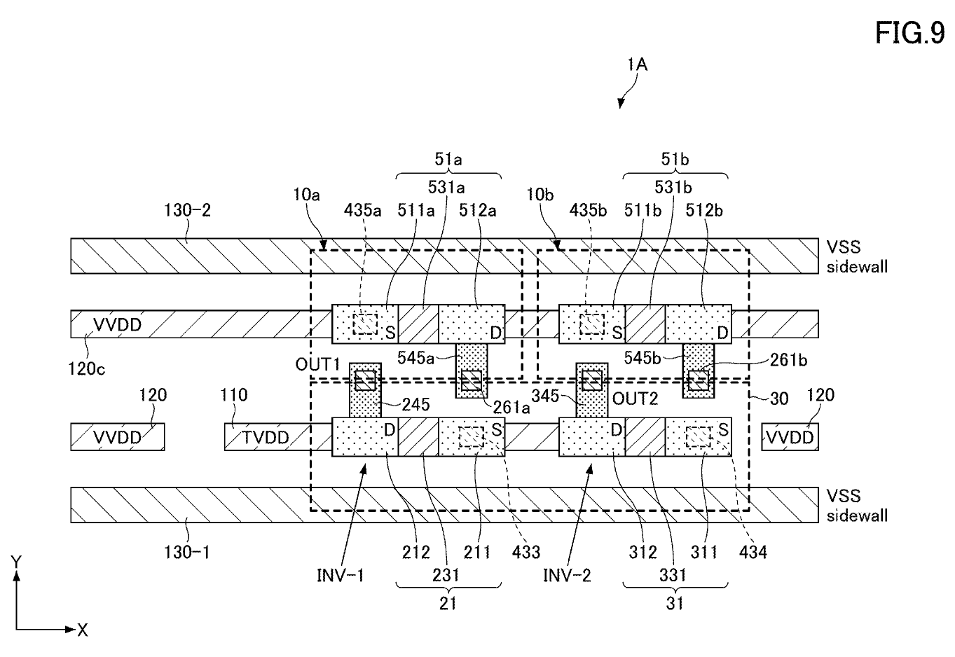

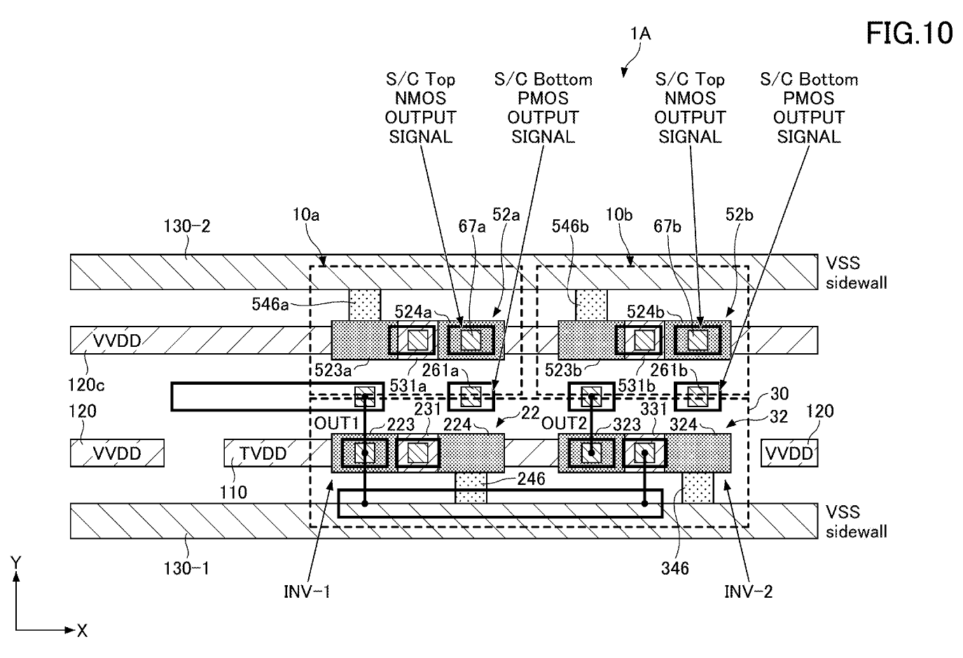

FIG. 9 is a plan view illustrating a bottom layer of a semiconductor device 1A of a first modification example, and FIG. 10 is a plan view illustrating a top layer of the first modification example. In the first modification example, a standard cell 10a is provided adjacent in the Y-direction to the inverter INV-1 of the control circuit 30. Accordingly, TVDD 110 and VVDD 120 are disposed between the first VSS sidewall 130-1 and the second VSS sidewall 130-2. In addition to the standard cell 10a, the standard cell 10b may be provided adjacent in the Y-direction to the inverter INV-2. In FIGS. 9 and 10, the switch transistor 40 is not shown.

In FIG. 9, the inverters INV-1 and INV-2 of the control circuit 30 are provided in a region overlapping TVDD 110 extending in the X-direction in plan view. A first VSS sidewall 130-1 extending in the X-direction deviating from TVDD 110 in the -Y-direction is arranged. The fifth semiconductor layer 211 of the bottom transistor 21 of the inverter INV-1 is connected to TVDD 110 on the back surface of the substrate 3 via the third through via 433, and the sixth semiconductor layer 212 is connected to the interconnect 245 extending in the Y-direction. A signal “OUT1” of the bottom transistor 21 of the inverter INV-1 is routed via the interconnect 245.

The source 311 of the bottom transistor 31 of the inverter INV-2 is connected to TVDD 110 on the back surface of the substrate 3 via the through via 434, and the drain 312 is connected to the interconnect 345 extending in the Y-direction. A signal “OUT2” of the bottom transistor 31 of the inverter INV-2 is routed via the interconnect 345.

A source 511a of a bottom transistor 51a of the standard cell 10a adjacent to the inverter INV-1 in the Y-direction is connected to VVDD 120c on the back surface of the substrate 3 via a through via 435a. A VSS sidewall 130-2 extending in the X-direction is disposed, deviating from VVDD 120c in the +Y-direction. A drain 512a of the bottom transistor 51a is connected to an interconnect 545a extending in the -Y-direction, and a signal of the bottom transistor 51a is routed via a via plug 261a. A gate 531a is provided between the source 511a and the drain 512a.

A source 511b of a bottom transistor 51b of a standard cell 10b adjacent to the inverter INV-2 in the Y-direction is connected to VVDD 120c on the back surface of the substrate 3 via a through via 435b. A drain 512b is connected to an interconnect 545b extending in the -Y-direction, and a signal of the bottom transistor 51b is routed via a via plug 261b.

Between TVDD 110 and VVDD 120c, the interconnect 245 connected to the sixth semiconductor layer 212 of the bottom transistor 21 of the inverter INV-1 and the interconnect 545a connected to the drain 512a of the bottom transistor 51a of the standard cell 10a are alternately arranged. Between TVDD 110 and VVDD 120c, the interconnect 345 connected to the drain 312 of the bottom transistor 31 of the inverter INV-2 and the interconnect 545b connected to the drain 512b of the bottom transistor 51b of the standard cell 10b are alternately arranged. With this arrangement, a region in which the interconnects 245, 545a, 345, and 545b are provided between adjacent transistors in the Y-direction is narrowed, and the area of the entire circuit can be reduced.

In FIG. 10, top transistors 22 and 32 are provided above the bottom transistors 21 and 31 of the inverters INV-1 and INV-2 of the control circuit 30, respectively. The eighth semiconductor layer 224 of the top transistor 22 of the inverter INV-1 is connected to the first VSS sidewall 130-1 via the interconnect 246. A signal “OUT1” is routed from the seventh semiconductor layer 223 of the top transistor 22, and an output signal of the inverter INV-1 is obtained together with a signal “OUT1” output from the sixth semiconductor layer 212 of the bottom transistor 21.

The source 324 of the top transistor 32 of the inverter INV-2 is connected to the first VSS sidewall 130-1 via the interconnect 346. A signal “OUT2” is routed from the drain 323 of the top transistor 32, and an output signal of the inverter INV-2 is obtained together with a signal “OUT2” output from the drain 312 of the bottom transistor 31.

A source 523a of a top transistor 52a of the standard cell 10a adjacent to the inverter INV-1 in the Y-direction is connected to the second VSS sidewall 130-2 via an interconnect 546a. An output signal of the top transistor 52a (also referred to as “Top NMOS” in the figure) is routed from a drain 524a via a via plug 67a.

A source 523b of a top transistor 52b of the standard cell 10b adjacent to the inverter INV-2 in the Y-direction is connected to the second VSS sidewall 130-2 via an interconnect 546b. The output signal of the top transistor 52b is routed from a drain 524b via a via plug 67b.

As described above with reference to FIG. 9, the output signal of the bottom transistor 51a of the standard cell 10a (also referred to as “bottom PMOS” in the figure) is routed via the via plug 261a, and the output signal of the bottom transistor 51b of the standard cell 10b is routed via the via plug 261b. This arrangement makes it possible to reduce the area of the entire circuit by reducing the area in which the via plugs for routing signals to the interconnect of the upper layer are provided between transistors adjacent in the Y-direction. Note that the output of one of the standard cells 10a and 10b may be input to the other. Further, in the standard cell 10a, the drain 524a of the top transistor 52a and the drain 512a of the bottom transistor 51a may be electrically connected. Further, in the standard cell 10b, the drain 524b of the top transistor 52b and the drain 512b of the bottom transistor 51b may be electrically connected.

### Second Modification Example

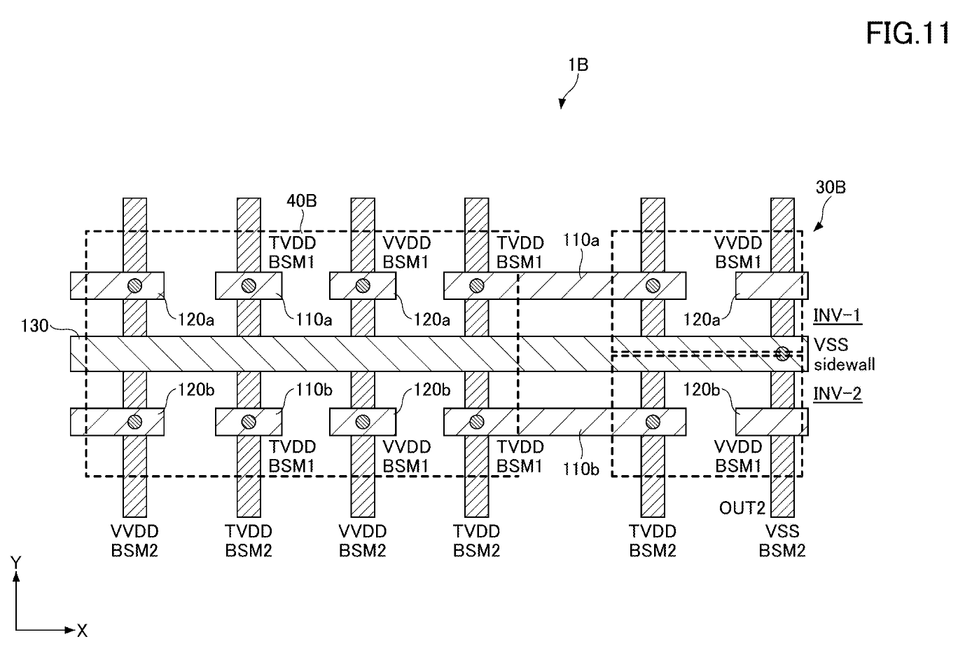

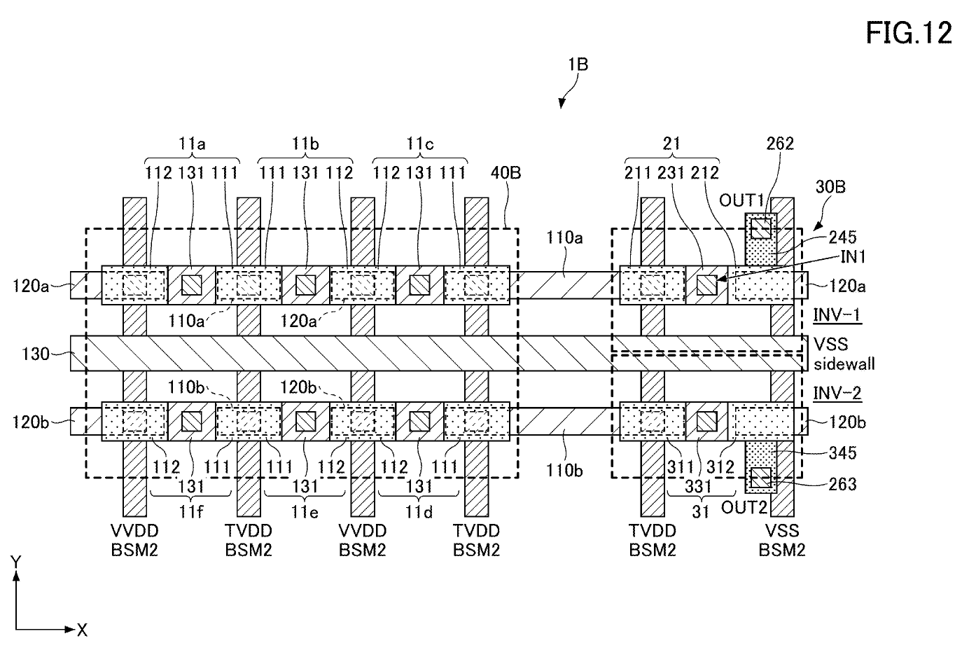

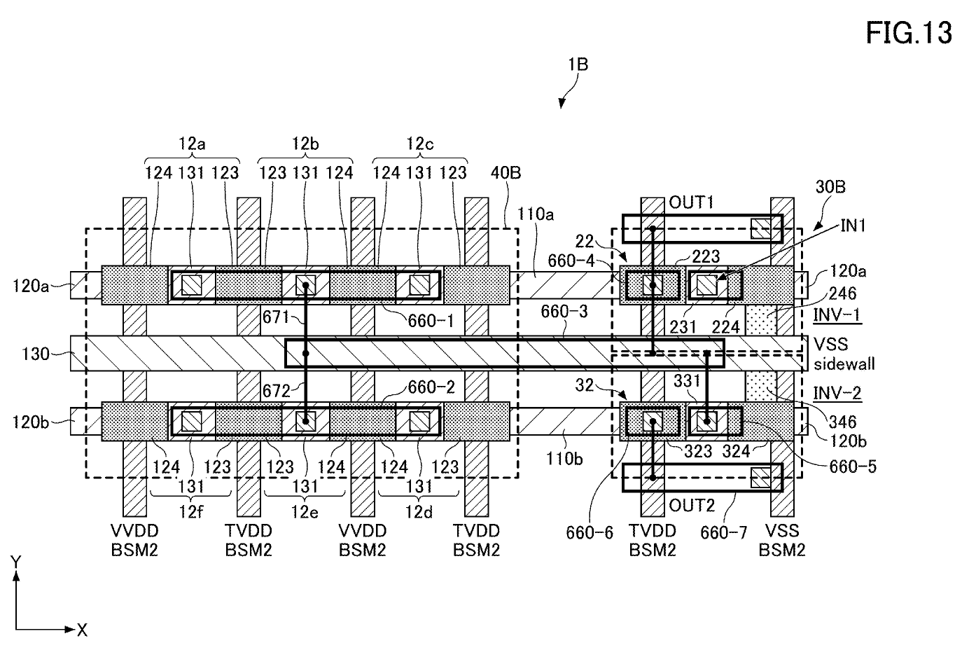

FIG. 11 is a plan view illustrating the BSM of a second modification example of a semiconductor device 1B, FIG. 12 is a plan view illustrating a bottom layer of the second modification example of the semiconductor device 1B, and FIG. 13 is a plan view illustrating a top layer of the second modification example of the semiconductor device 1B. In the second modification example, a switch transistor 40B is formed of a plurality of transistors arranged on both sides of the VSS sidewall 130 in the Y-direction. Accordingly, the inverters INV-1 and INV-2 of a control circuit 30B are made adjacent to each other in the Y-direction.

In FIG. 11, on one side of the VSS sidewall 130 extending in the X-direction, TVDD 110a and VVDD 120a extending in the X-direction are alternately arranged, and on the other side, TVDD 110b and VVDD 120b extending in the X-direction are alternately arranged. TVDDs 110a and 110b are connected to corresponding TVDD interconnects (denoted as “TVDD BSM2” in the figure) of the back surface second layer, and VVDDs 120a and 120b are connected to corresponding VVDD interconnects (denoted as “VVDD BSM2” in the figure) of the back surface second layer. The VSS sidewall 130 is connected to VSS interconnects (denoted as “VSS BSM2” in the figure) of the back surface second layer.

In FIG. 12, on the front surface 302 of the substrate 3, the fifth semiconductor layer 211 of the bottom transistor 21 of the inverter INV-1 is provided at a position overlapping TVDD 110a of the back surface 301 of the substrate 3, and the sixth semiconductor layer 212 is provided at a position overlapping VVDD 120a. The gate 231 is provided between the fifth semiconductor layer and the sixth semiconductor layer 212. A signal “OUT1” of the bottom transistor 21 of the inverter INV-1 is routed via a via plug 262 connected to the interconnects 245 extending from the sixth semiconductor layer 212 in the +Y-direction.

The source 311 of the bottom transistor 31 of the inverter INV-2 adjacent to the inverter INV-1 in the -Y-direction is provided at a position overlapping TVDD 110b on the back surface 301 of the substrate 3, and the drain 312 is provided at a position overlapping VVDD 120b. The gate 331 is provided between the source 311 and the drain 312. A signal “OUT2” of the inverter INV-2 is routed via a via plug 263 connected to the interconnect 345 extending from the drain 312 in the -Y-direction.

In the switch transistor 40B, a plurality of first transistors 11a to 11f are provided on both sides of the VSS sidewall 130 in the Y-direction. The first semiconductor layer 111 is provided at a position overlapping TVDDs 110a and 110b on the back surface 301 of the substrate 3, and the second semiconductor layer 112 is provided at a position overlapping VVDDs 120a and 120b. The gate 131 is provided between the first semiconductor layer 111 and the second semiconductor layer 112. The first transistors 11a, 11b, and 11c are connected in parallel on the +Y side of the VSS sidewall 130, and the first transistors 11d, 11e, and 11f are connected in parallel on the -Y side of the VSS sidewall 130. The whole of the first transistors 11a to 11f (collectively referred to as “first transistor 11”, as appropriate) connected in parallel may be used as the switch transistor 40B. By using a plurality of first transistors 11 connected in parallel, the scale of the switch transistor 40B can be increased and a large current of the standard cell 10 can be supplied.

In the configuration example shown in FIG. 12, the inverter INV-1 and TVDD 110a are shared, and the inverter INV-2 and TVDD 110b are shared, using the first semiconductor layer 111 at the right end (end in the +X-direction) of the switch transistor 40B as a source. This is an example of the arrangement and depending on the arrangement of the source/drain of the switch transistor 40B, the right end of the switch transistor 40B may be positioned to overlap VVDD 120a and VVDD 120b on the back surface.

In FIG. 13, a plurality of top transistors 12a to 12f are provided above the plurality of first transistors 11a to 11f of the switch transistor 40B. The gate 131 of the transistor provided on the +Y side of the VSS sidewall 130 and the gate 131 of the transistor provided on the − Y side of the VSS sidewall 130 are connected via upper layer interconnects 671 and 672, and the first transistors 11a to 11f are connected in parallel. By using the plurality of first transistors 11 connected in parallel, the scale of the switch transistor 40B can be increased, and a large current of the standard cell 10 can be supplied.

In the control circuit 30B, the top transistor 22 is provided above the bottom transistor 21 of the inverter INV-1. The eighth semiconductor layer 224 of the top transistor 22 is connected to the VSS sidewall 130 via the interconnect 246, and the seventh semiconductor layer 223 is connected to an upper interconnect 660-4. The signal “OUT1” output from the seventh semiconductor layer of the top transistor 22, together with the signal “OUT1” output from the sixth semiconductor layer 212 of the bottom transistor 21, is applied to the gate 131 of the switch transistor 40B via upper interconnects 660-4, 660-3, 660-1, and 660-2 as an output signal of the inverter INV-1. The signal “OUT1” output from the inverter INV-1 may be applied to the gate 331 of the inverter INV-2 via upper interconnects 660-4, 660-3, and 660-5. In this manner, one of the source/drain of the top transistor 22 of the inverter INV-1 is connected to the VSS sidewall 130 via the interconnect 246, and the other is electrically connected to the sixth semiconductor layer 212 of the bottom transistor 21 and the gate 131 of the switch transistor 40.

In the configuration of the second modification example, TVDDs 110a and 110b are shared between the control circuit 30B and the switch transistor 40B to achieve a compact arrangement.

Further, the present invention is not limited to these embodiments, and various variations and modifications may be made without departing from the scope of the present invention. For each of the bottom and top transistors forming each CFET, the selection of which semiconductor layer provided on either side of the gate is used as a source and which is used as a drain is determined by design. In the switch

transistor 40B of the second modification, the number of the first transistors 11 provided on each side of the VSS sidewall 130 is not limited to three, and one, two, four, or more first transistors may be provided as switch transistors. The position where the gates of the first transistors on both sides of the VSS sidewall 130 are connected to each other does not necessarily need to be the center transistor, and the gates of the first transistor 11 positioned at the extreme end of the switch transistor 40B may be connected in parallel. With the configuration of the embodiment and the modified example, when the CFET is positioned in the vicinity of the VSS sidewall (or power wall), the layout of the power switch circuit 20, in particular, the efficient layout of the control circuit 30 and the switch transistor 40, can be achieved.

What is claimed is:

1. A semiconductor device comprising:
a substrate;
a first power supply line and a second power supply line extending in a first direction in plan view on a first surface of the substrate;
a conductive wall extending in the first direction and disposed offset from the first power supply line and the second power supply line in a second direction different from the first direction in plan view;
a first semiconductor layer and a second semiconductor layer disposed on a second surface of the substrate opposite to the first surface, the first semiconductor layer being disposed at a position overlapping with the first power supply line in plan view, and the second semiconductor layer being disposed at a position overlapping with the second power supply line in plan view;
a first through via formed in the substrate and connecting the first power supply line and the first semiconductor layer;
a second through via formed in the substrate and connecting the second power supply line and the second semiconductor layer;
a third semiconductor layer formed above the first semiconductor layer;
a fourth semiconductor layer formed above the second semiconductor layer;
a first gate disposed between the first semiconductor layer and the second semiconductor layer, and the third semiconductor layer and the fourth semiconductor layer;
a first transistor including the first semiconductor layer, the second semiconductor layer, and the first gate; and
a control circuit configured to control the first transistors, wherein:
the control circuit includes:
a fifth semiconductor layer and a sixth semiconductor layer, each formed on the second surface at a position overlapping with the first power supply line in plan view;
a third through via each formed in the substrate and connecting the fifth semiconductor layer and the first power supply lines;
a seventh semiconductor layer formed above the fifth semiconductor layer;
an eighth semiconductor layer formed above the sixth semiconductor layer;
a second gate disposed between the fifth semiconductor layer and the sixth semiconductor layer, and the seventh semiconductor layer and the eighth semiconductor layer;
a second transistor including the fifth semiconductor layer, the sixth semiconductor layer, and the second gate; and
a third transistor including the seventh semiconductor layer, the eighth semiconductor layer, and the second gate, and
one of the seventh semiconductor layer or the eighth semiconductor layer is electrically connected to the conductive wall, and the other one of the seventh semiconductor layer or the eighth semiconductor layer is electrically connected to the sixth semiconductor layer and the first gate of the first transistor.

2. The semiconductor device according to claim 1, wherein the first power supply line is arranged in the first direction between at least two of the second power supply lines on the second surface in plan view.

3. The semiconductor device according to claim 1, wherein:
the first transistor and the second transistor are disposed side by side in the first direction on one side of the conductive wall extending in the first direction in plan view;
a standard cell is arranged on the other side of the conductive wall in plan view; and
the standard cell and the conductive wall are electrically connected.

4. The semiconductor device according to claim 1, further comprising a third power supply line electrically connected to the second power supply line and extending in the first direction on the first surface of the substrate, wherein:
the conductive wall includes:
a first conductive wall positioned adjacent to the first power supply line in the second direction and extending in the first direction; and
a second conductive wall positioned adjacent to the third power supply line in the second direction;
the first power supply line and the third power supply line are arranged side by side in the second direction between the first conductive wall and the second conductive wall;
a standard cell positioned adjacent to the control circuit in the second direction is disposed at a position overlapping with the third power supply line in plan view;
the third transistor is electrically connected to the first conductive wall; and
the standard cell is electrically connected to the second conductive wall.

5. The semiconductor device according to claim 4, further comprising:
a first interconnect extending from the sixth semiconductor layer of the second transistor in the second direction; and
a second interconnect extending from the standard cell in a direction opposite to the first interconnect,
wherein the first interconnect and the second interconnect are arranged in a staggered manner between the first power supply line and the second power supply line.

6. The semiconductor device according to claim 1, wherein:
a plurality of the first power supply lines and a plurality of the second power supply lines are alternately arranged in the first direction in plan view on at least one side of the conductive wall; and
a plurality of the first transistors are connected in parallel on at least one side of the conductive wall.
